(19) United States
(12) Patent Application Publication
(10) Pub. No.: US 2025/0289074 A1
(43) Pub. Date: Sep. 18, 2025

(54) ULTRASONIC WELDING SYSTEMS, AND SONOTRODES FOR ULTRASONIC WELDING SYSTEMS

(71) Applicant: Kulicke and Soffa Industries, Inc., Fort Washington, PA (US)

(72) Inventors: Todd Walker, Huntington Beach, CA (US); Henri Seppaenen, Irvine, CA (US)

(73) Assignee: Kulicke and Soffa Industries, Inc., Fort Washington, PA (US)

(21) Appl. No.: 19/071,983

(22) Filed: Mar. 6, 2025

Related U.S. Application Data
(60) Provisional application No. 63/565,931, filed on Mar. 15, 2024.
(60) Provisional application No. 63/669,740, filed on Jul. 11, 2024.

(51) Int. Cl. B23K 20/10

(52) U.S. Cl. CPC B23K 20/106

(57) ABSTRACT

A sonotrode configured for use in an ultrasonic welding system is provided. The sonotrode includes a body portion terminating at a tip portion, the tip portion including a working surface. The working surface defines an aperture configured to hold a conductive pin during an ultrasonic welding process. The working surface also defines a plurality of linear depressions. Each of the plurality of linear depressions follows a path that does not intersect the aperture.

### CROSS-REFERENCE TO RELATED APPLICATIONS

This application claims the benefit of U.S. Provisional Application No. 63/565,931, filed Mar. 15, 2024, and U.S. Provisional Application No. 63/669,740, filed Jul. 11, 2024, the contents of both of which are incorporated herein by reference.

### FIELD

The invention relates to the ultrasonic welding, and more particularly, to improved sonotrodes for use in ultrasonic welding systems, such as ultrasonic welding systems for conductive pin welding.

### BACKGROUND

Ultrasonic energy is widely used in forming interconnections between two or more materials. For example, wire bonding machines (e.g., ball bonding machines, wedge bonding machines, ribbon bonding machines, etc.) are used to bond a wire or ribbon to a bonding location. Wire bonding utilizes relatively low levels of energy (e.g., bond force, ultrasonic energy, etc.). Exemplary wire bonding machines are marketed by Kulicke and Soffa Industries, Inc. of Fort Washington, Pennsylvania.

Certain applications involve joining of materials other than wire. Welding has been considered for such applications. Ultrasonic welding is also a widely used technology. Ultrasonic welding may use an ultrasonic converter (e.g., carrying a sonotrode) for converting electrical energy into mechanical movement/scrub (e.g., linear movement/scrub, torsional movement/scrub, etc.). However, existing ultrasonic welding technology and equipment is limited in its ability to provide solutions that can satisfy market demand in terms of cost, operational efficiency, flexibility, portability, and related factors.

U.S. Pat. No. 10,882,134 (entitled “Ultrasonic Welding Systems and Methods of Using the Same”), U.S. Pat. No. 11,364,565 (entitled “Ultrasonic Welding Systems and Methods of Using the Same”), and U.S. Pat. No. 11,850,676 (entitled “Ultrasonic Welding Systems, Methods of Using the Same, and Related Workpieces Including Welded Conductive Pins”), U.S. Pat. No. 12,070,814 (entitled “Ultrasonic Welding Systems, Methods of Using the Same, and Related Workpieces Including Welded Conductive Pins”), U.S. Patent Application Publication No. 2024/0359255 (entitled “Ultrasonic Welding Systems, Methods of Using the Same, and Related Workpieces Including Welded Conductive Pins”), U.S. Patent Application Publication No. 2024/0351132 (entitled “Ultrasonic Welding Systems for Conductive Pins, and Related Methods”), International Patent Publication No. WO2024/0220203 (entitled “Ultrasonic Welding Systems, Sonotrodes and Conductive Pins for Such Systems, and Related Methods and Workpieces”), assigned to Kulicke and Soffa Industries, Inc., relate to improvements in ultrasonic welding technology, and are incorporated by reference in their entirety.

Still, improvements are needed in connection with specific applications of ultrasonic welding, including ultrasonic pin welding. For example, in ultrasonic pin welding, unwelded material of conductive pins may form undesired “whiskers” (e.g., long strands of unwelded material), where such whiskers may result in short circuiting in a workpiece. Thus, it would be desirable to provide improved sonotrodes, and ultrasonic welding systems including such sonotrodes, configured for use in connection with ultrasonic pin welding.

### SUMMARY

According to an exemplary embodiment of the invention, a sonotrode configured for use in an ultrasonic welding system is provided. The sonotrode includes a body portion terminating at a tip portion, the tip portion including a working surface. The working surface defines an aperture configured to hold a conductive pin during an ultrasonic welding process. The working surface also defines a plurality of linear depressions. Each of the plurality of linear depressions follows a path that does not intersect the aperture.

According to other embodiments of the invention, the sonotrode recited in the immediately preceding paragraph may have any one or more of the following features: each of the plurality of linear depressions extends across the working surface; the plurality of linear depressions collectively define a star shaped pattern; the plurality of linear depressions collectively define a plurality of V-shaped patterns around a peripheral portion of the working surface; the working surface includes a smooth portion, and the plurality of linear depressions are disposed around a peripheral portion of the working surface; the working surface further defines an annular depression between the aperture and an edge of the working surface; the body portion and the tip portion are formed from a unitary piece of material; the body portion and the tip portion are separate pieces coupled together; the tip portion includes a chamfered portion between the working surface and a terminal end of the sonotrode; and/or the chamfered portion is configured to align the conductive pin with respect to the aperture in connection with the ultrasonic welding process.

According to another exemplary embodiment of the invention, a sonotrode configured for use in an ultrasonic welding system is provided. The sonotrode includes a body portion terminating at a tip portion, the tip portion including a working surface. The working surface defines an aperture configured to hold a conductive pin during an ultrasonic welding process. The working surface defines an annular depression between the aperture and an edge of the working surface.

According to other embodiments of the invention, the sonotrode recited in the immediately preceding paragraph may have any one or more of the following features: the working surface includes a roughened portion; the working surface includes a patterned portion; the working surface includes a plurality of depressions; the plurality of depressions are a plurality of linear grooves; the plurality of linear grooves are arranged in a pattern; the body portion and the tip portion are formed from a unitary piece of material; the body portion and the tip portion are separate pieces coupled together; the tip portion includes a chamfered portion between the working surface and a terminal end of the sonotrode; and/or the chamfered portion is configured to align the conductive pin with respect to the aperture in connection with the ultrasonic welding process.

According to yet another exemplary embodiment of the invention, a sonotrode configured for use in an ultrasonic welding system is provided. The sonotrode includes a body portion terminating at a tip portion, the tip portion including a working surface. The working surface defines an aperture configured to hold a conductive pin during an ultrasonic welding process. The sonotrode defines a cavity adjacent the working surface. The cavity is defined by the working surface and a peripheral wall. A pin head of the conductive pin is configured to be received by the cavity.

According to other embodiments of the invention, the sonotrode recited in the immediately preceding paragraph may have any one or more of the following features: the peripheral wall is a circular wall that surrounds the working surface; the peripheral wall extends perpendicularly from the working surface; the peripheral wall is configured to mitigate (e.g., reduce, prevent, etc.) outflow of material resulting from the ultrasonic welding process; the working surface includes a roughened portion; the working surface includes a patterned portion; the working surface includes a plurality of linear grooves; the plurality of linear grooves are arranged in a pattern; the working surface includes a plurality of protrusions; the plurality of protrusions are laser scribed protrusions; the plurality of protrusions are arranged in a plurality of concentric rings, each of the plurality of concentric rings including a portion of the plurality of protrusions; the body portion and the tip portion are formed from a unitary piece of material; the body portion and the tip portion are separate pieces coupled together; the peripheral wall is a chamfered wall between the working surface and a terminal end of the sonotrode; and/or the chamfered wall is configured to align the conductive pin with respect to the aperture in connection with the ultrasonic welding process.

According to other embodiments of the invention, ultrasonic welding systems are provided including any combination of the features recited in the immediately preceding six paragraphs, and features disclosed within this application (e.g., a support structure configured for supporting a workpiece, a weld head assembly including an ultrasonic converter for carrying a sonotrode, etc.), and/or other features within the scope of the invention.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1B are cross-sectional block diagram side views of portions of sonotrodes in connection with ultrasonic welding operations in accordance with various exemplary embodiments of the invention;

FIGS. 1C-1E are end views of the working surfaces of the sonotrodes of FIGS. 1A-1B, including various alternative working surfaces, in accordance with various exemplary embodiments of the invention;

FIGS. 2A-2B are cross-sectional block diagram side views of portions of sonotrodes in connection with ultrasonic welding operations in accordance with various exemplary embodiments of the invention;

FIGS. 2C-2D are end views of the working surfaces of the sonotrodes of FIGS. 2A-2B, including various alternative working surfaces, in accordance with various exemplary embodiments of the invention;

FIG. 3A is a cross-sectional block diagram side view of a portion of yet another sonotrode in connection with an ultrasonic welding operation in accordance with an exemplary embodiment of the invention;

FIG. 3B is a detailed cross-sectional block diagram side view of a portion of the sonotrode of FIG. 3A;

FIG. 3C is an end view of the sonotrode of FIG. 3A, including an alternative working surface, in accordance with an exemplary embodiment of the invention;

FIG. 3D is a perspective view of a tip portion of yet another sonotrode in connection with an ultrasonic welding operation in accordance with an exemplary embodiment of the invention;

FIG. 3E is an end view of the tip portion of the sonotrode of FIG. 3D; FIG. 3F is a detailed view of a portion of FIG. 3E;

FIG. 3G is a perspective view of a tip portion of yet another sonotrode in connection with an ultrasonic welding operation in accordance with an exemplary embodiment of the invention;

FIG. 3H is an end view of the tip portion of the sonotrode of FIG. 3G; and

FIG. 4 is a block diagram side view of an ultrasonic welding system including a sonotrode (e.g., being one or more of the sonotrodes illustrated in FIGS. 1A-1E, FIGS. 2A-2D, and FIGS. 3A-3H) in accordance with various exemplary embodiments of the invention.

### DETAILED DESCRIPTION

Sonotrodes used in connection with an ultrasonic welding system (e.g., configured to ultrasonically weld, such as through torsional motion, conductive pins to a workpiece) are described herein. Certain exemplary embodiments of sonotrodes disclosed herein provide certain advantages in the mitigation of unwelded material (e.g., of conductive pins) produced in certain ultrasonic welding operations (e.g., pin welding operations). In certain applications, unwelded materials may form undesired “whiskers” which can be described as strands (e.g., long strands) of unwelded material produced in ultrasonic welding operations. Such “whiskers” can cause undesired results, such as contributing to short circuiting of the welded workpiece and/or nearby electronic components (e.g., semiconductor elements). In accordance with certain exemplary embodiments of the invention, sonotrodes are provided whereby excess welding material (which conventionally may be formed into undesired “whiskers”) is mitigated (e.g., captured using an annular depression, captured using a peripheral wall, minimizing a length of any whiskers, and/or substantially containing any whiskers within the welded portion of the conductive pin).

As used herein, the term “conductive pin” is intended to refer to any conductive structure intended to be welded (e.g., ultrasonically welded) to a workpiece. The conductive pin may have a free end (after being welded to a workpiece), and a body portion of the conductive pin may extend substantially vertically from a “welded” end to the free end. The cross section of the conductive pin may be round, square, rectangular, or have any desired cross section. The term conductive pin shall also be construed to include conductive receptacles or sleeves (e.g., having a tubular shape such as a rivet), where the conductive receptacle/sleeve is ultrasonically welded to a workpiece, and configured to receive another conductive element.

As used herein, “peripheral” is intended to be interpreted broadly to mean of, at, or near an external boundary or surface (e.g., of a working surface of a sonotrode, etc.). Similarly, “circumference” and “circumferential” are intended to refer to a perimeter of a shape, such as a circle, an oval, a rectangle, and/or any other geometric shape.

As used herein, “annular” is intended to be interpreted broadly to mean a rounded shape (e.g., a circle, a ring, a ringlike shape, an anulus, an ellipse, an oval, etc.) surrounding a point (e.g., an aperture). It should be understood that any other polygonal and/or geometric shape surrounding a central point may, in certain embodiments, be referred to as “annular” within the scope of the invention.

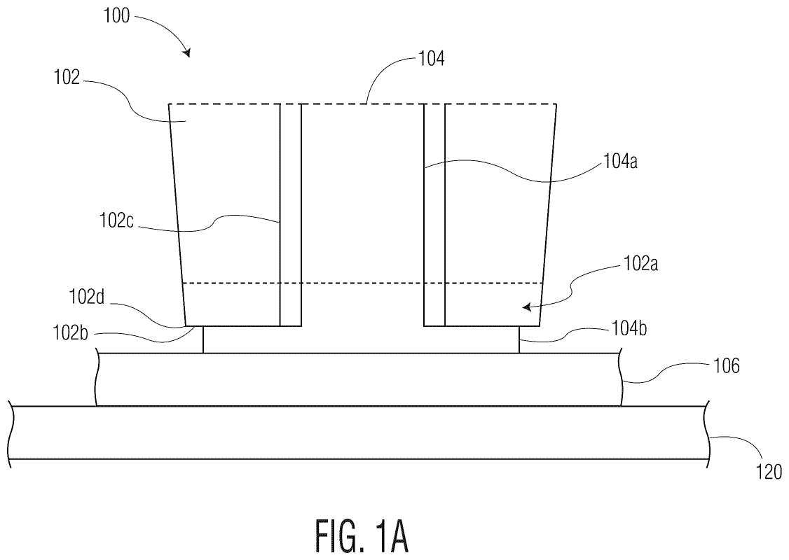

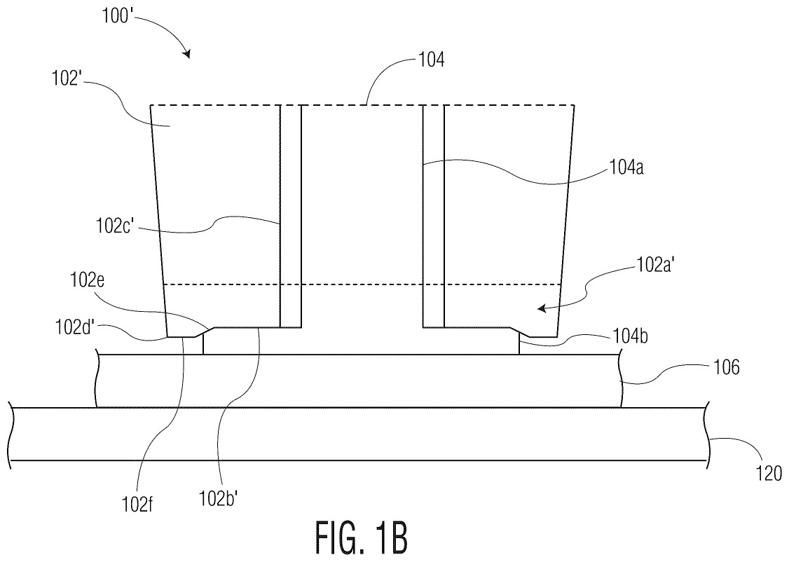

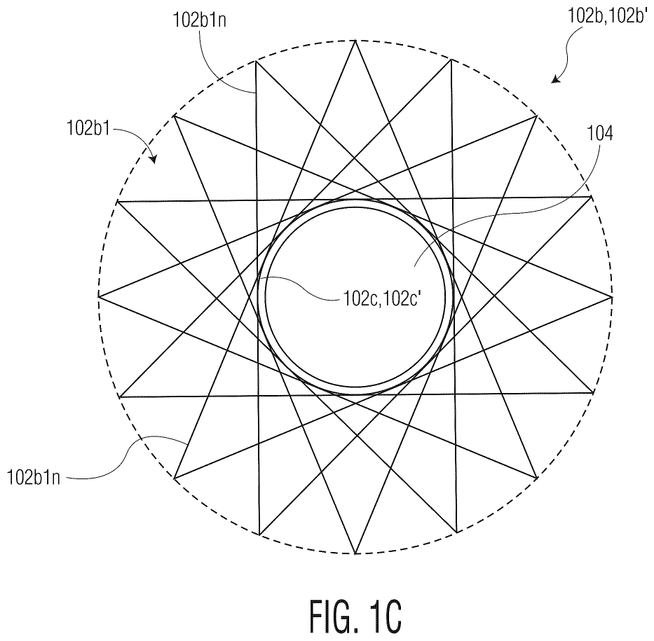

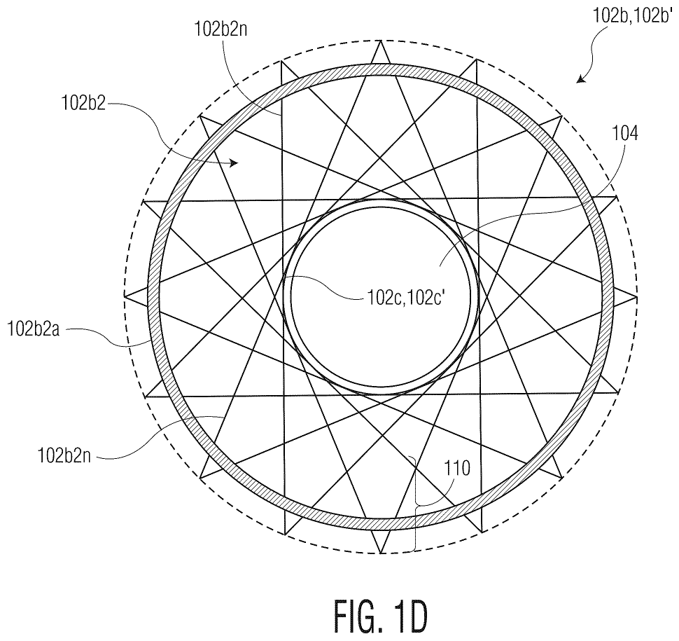

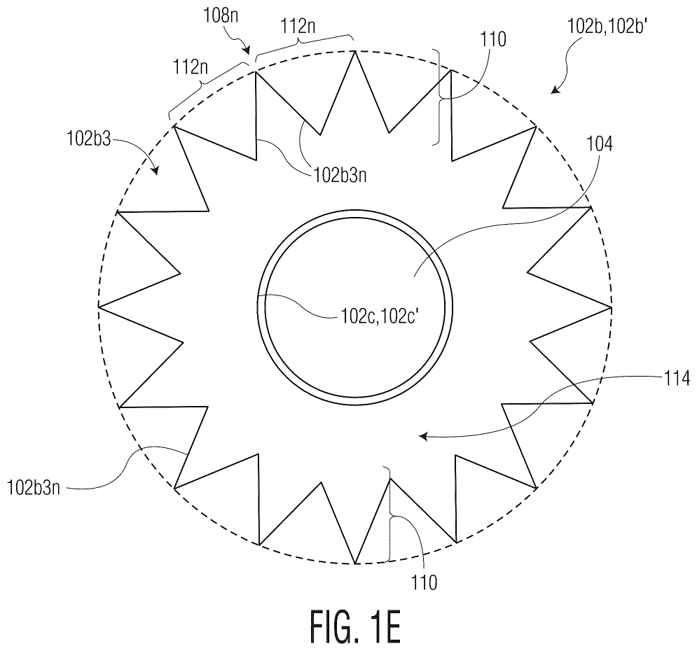

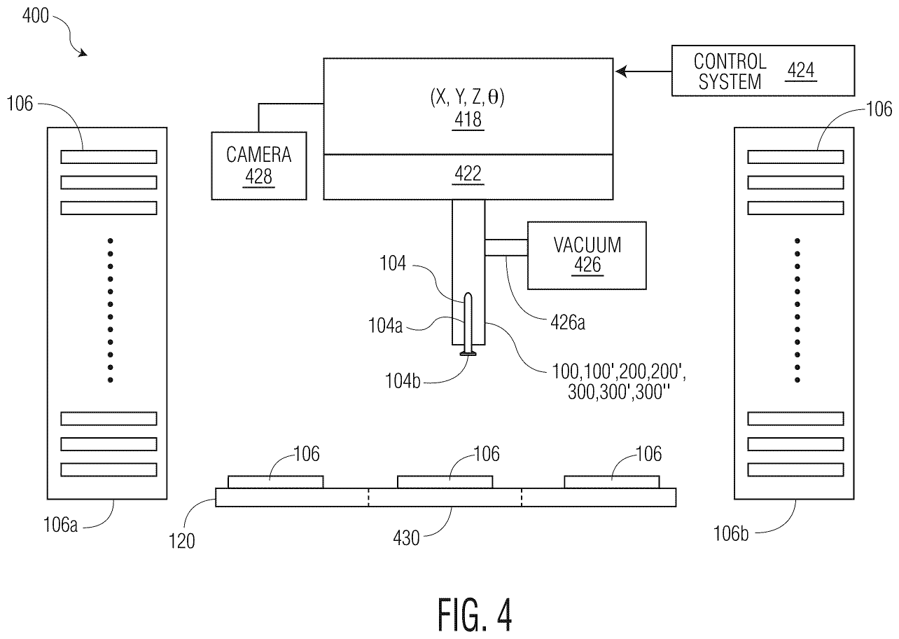

Referring now to the drawings, FIG. 1A illustrates a portion of a sonotrode 100 configured for use in an ultrasonic welding system (e.g., ultrasonic welding system 400 of FIG. 4). Sonotrode 100 is illustrated in connection with an ultrasonic welding operation, where a conductive pin 104 is being welded to a workpiece 106 (e.g., a substrate, a semiconductor element, a power module, etc.) supported by a support structure 120 (e.g., of an ultrasonic welding system). Sonotrode 100 is configured to ultrasonically weld conductive pin 104 to workpiece 106 during a welding process (e.g., an ultrasonic welding process, an ultrasonic welding operation, etc.). Conductive pin 104 is illustrated including a body portion 104a and a head portion 104b. Sonotrode 100 includes a body portion 102 including a tip portion 102a, where tip portion 102a includes a working surface 102b. Working surface 102b defines an edge 102d (e.g., a circumferential edge, an annular edge, etc.) and also defines (at least in part) an aperture 102c. Aperture 102c (and/or body portion 102a) is configured to hold conductive pin 104 during an ultrasonic welding process (e.g., by providing enough space for conductive pin 104 during an ultrasonic welding process).

FIG. 1B illustrates a portion of a sonotrode 100′ (including a body portion 102′ terminating at a tip portion 102a′) configured for use in an ultrasonic welding system (e.g., ultrasonic welding system 400 of FIG. 4). Sonotrode 100′ is similar to sonotrode 100 of FIG. 1A, except that sonotrode 100′ includes a tip portion 102a′ in lieu of tip portion 102a. Sonotrode 100′ also includes an aperture 102c′ and an edge 102d′, in lieu of aperture 102c and edge 102d. It should be understood that like reference numerals denote like elements. Tip portion 102a′ includes a working surface 102b′, a chamfered portion 102e (e.g., a tapered portion, a filleted portion, etc.), and a terminal end 102f (e.g., a surface parallel to working surface 102b′, a non-contact portion, a portion surrounding at least a portion of conductive pin 104, etc.). Chamfered portion 102e is illustrated between working surface 102b′ and terminal end 102f. As illustrated, when conductive pin 104 is welded using sonotrode 100′, the portion of head portion 104b contacting chamfered portion 102e is deformed (e.g., crushed). Chamfered portion 102e may be configured to align conductive pin 104 with respect to aperture 102c′ in connection with an ultrasonic welding process (e.g., the pin may become aligned through engagement with the peripheral wall in the presence of vacuum in the sonotrode). Chamfered portion 102e provides certain benefits when used in connection with an ultrasonic welding operation, such as: providing a centering function (e.g., aligning) when engaging conductive pin 104 with sonotrode 100′; providing an excess material (e.g., “whiskers”) collection function; among others.

It should be understood that FIGS. 1A-1B omit certain elements that may appear in FIGS. 1C-1E. For example, an annular depression 102b2a of FIG. 1D is omitted, although such an element may be applicable to the embodiments illustrated in FIGS. 1A-1B.

FIGS. 1C-1E illustrate, respectively, working surfaces which may be disposed on embodiments of sonotrode 100 and/or sonotrode 100′, namely a working surface 102b1, a working surface 102b2, and a working surface 102b3. It should be understood that certain repetitive or redundant reference numerals may be omitted for clarity.

Referring specifically to FIG. 1C, working surface 102b1 is illustrated. Working surface 102b1 defines a plurality of linear depressions 102b1n (in the exemplary illustration, thirty-two (32) linear depressions 102b1n are illustrated). Each of the plurality of linear depressions 102b1n (e.g., a plurality of grooves) follows a path (e.g., a linear path) that does not intersect aperture 102c, 102c′. Although each of the plurality of linear depressions 102b1n are illustrated substantially tangent to aperture 102c, 102c′, it should be understood that each of the plurality of linear depressions 102b1n may be disposed at any position (e.g., not tangent to aperture 102c, 102c′), so long as the path of each of the plurality of linear depressions 102b1n does not intersect aperture 102c, 102c′.

In the illustrated embodiment of FIG. 1C, each of the plurality of linear depressions 102b1n extends across working surface 102b1. The plurality of linear depressions 102b1n collectively define a star polygon (e.g., a regular star polygon) and/or a star pattern. It should be understood in certain embodiments a plurality of depressions disposed on a working surface may not be linear (e.g., where the path of each depression is defined by a curve or parabola that does not intersect aperture 102c, 102c′).

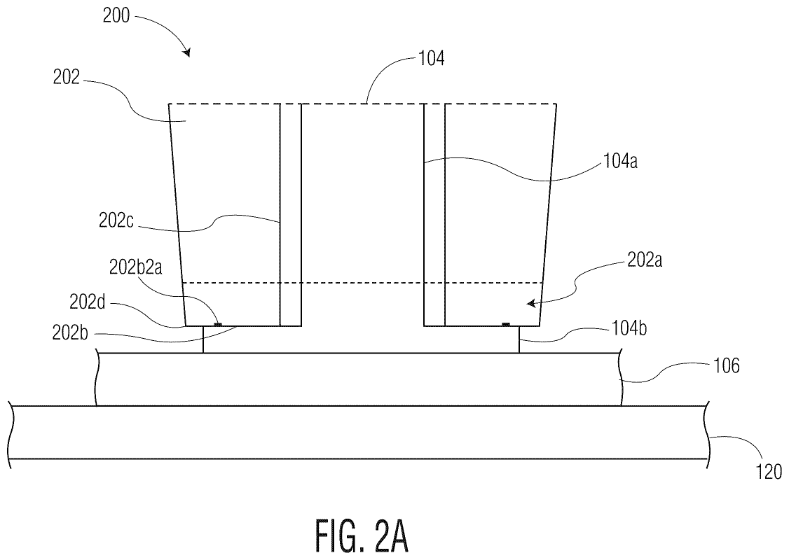

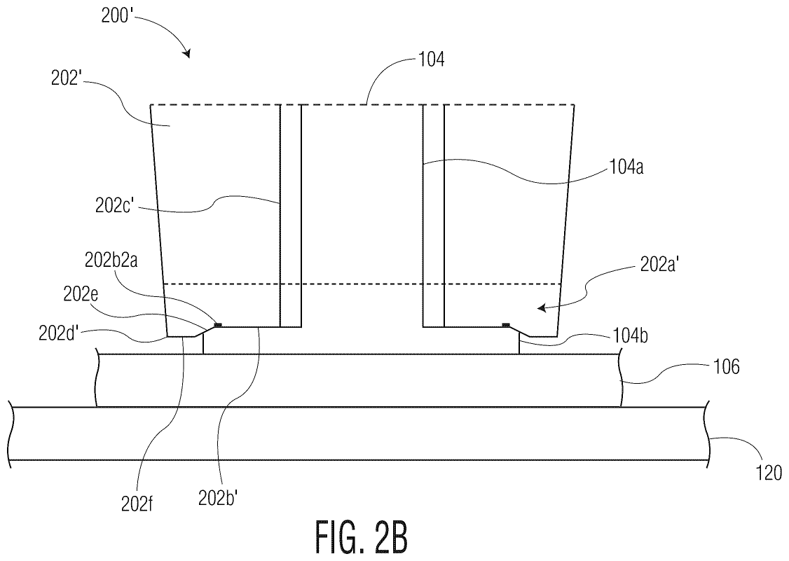

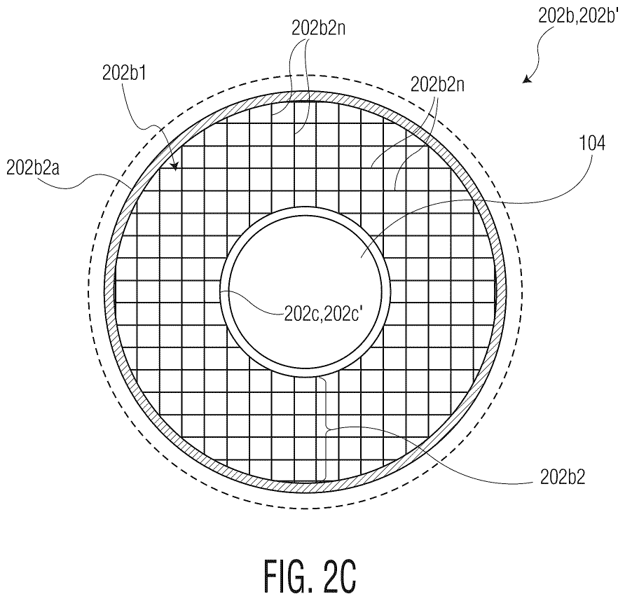

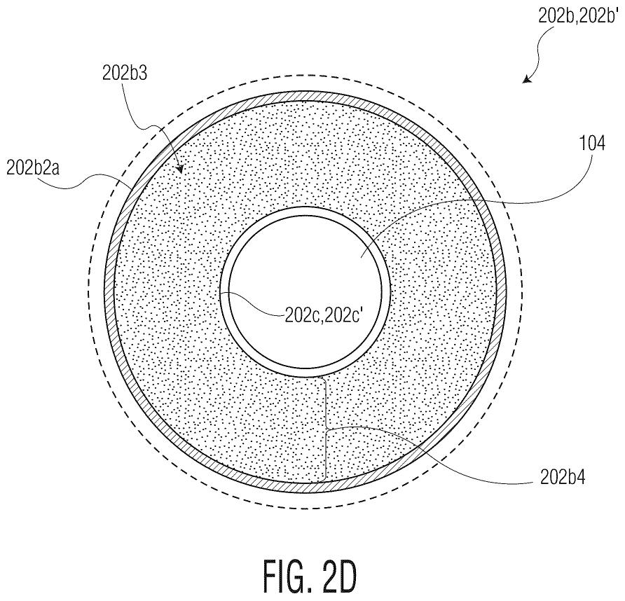

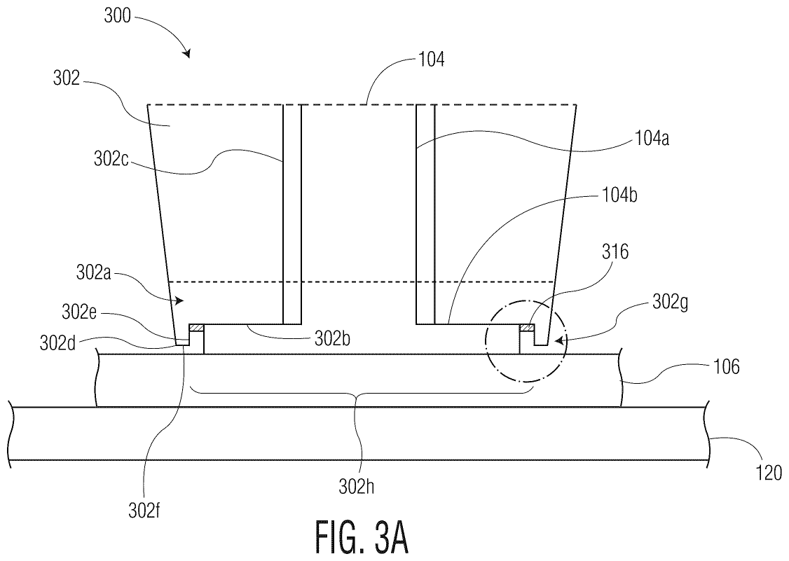

Referring now to FIG. 1D, working surface 102b2 is illustrated. Working surface 102b2 is similar to working surface 102b1 in many ways. Working surface 102b2 defines a plurality of linear depressions 102b2n (note certain reference numerals are omitted for clarity). Working surface 102b2 further defines annular depression 102b2a near a peripheral portion 110, between aperture 102c, 102c′ and the outer edge (e.g., edge 102d of FIG. 1A, edge 102d′ of FIG. 2B) of working surface 102b2.

Referring now to FIG. 1E, working surface 102b3 is illustrated. Working surface 102b3 defines a plurality of linear depressions 102b3n (note certain reference numerals are omitted for clarity). Each of the plurality of linear depressions 102b3n may be a groove.

Each of the plurality of linear depressions 102b3n follows a path (e.g., a linear path of an extended linear depression 102b3n) that does not intersect aperture 102c, 102c′. As illustrated, the plurality of linear depressions 102b3n includes a plurality of angle shapes 108n disposed around peripheral portion 110 of working surface 102b3. Each of the plurality of angle shapes 108n are illustrated as a “V”-shaped pattern. Thus, a plurality of sector-shaped patterns 112n (e.g., a wedge-like shape) are disposed around peripheral portion 110 of working surface 102b3. Working surface 102b3 includes a smooth portion 114 (wherein the plurality of linear depressions 102b3n are disposed around peripheral portion 110). It should be understood that smooth portion 114 may be roughened, as may be appropriate in an ultrasonic welding application. Smooth portion 114 may be defined as an area lacking any linear depressions.

In certain embodiments, working surface 102b3 can further define another depression, such as an annular depression (e.g., see annular depression 102b2a of FIG. 1D), between aperture 102c, 102c′ and the outer edge (e.g., edge 102d, 102d′) of working surface 102b3.

In the exemplary embodiment of FIG. 1E, the plurality of linear depressions 102b3n are not contiguous (e.g., extending from one end/edge of working surface 102b3 to another end/edge of working surface 102b3). While the linear depressions of FIGS. 1C-1E are illustrated as straight lines or line segments, the invention is not so limited. For example, it is contemplated that curves (e.g., curved line segments, curved lines, ellipses, parabolas, and the like) that do not pass through aperture 102c, 102c′ may be used in certain embodiments. Further, other depressions are contemplated such as circular depressions, zig-zag shaped depressions, etc.

Referring now to FIG. 2A, a portion of a sonotrode 200 (including a body portion 202 terminating at a tip portion 202a) configured for use in an ultrasonic welding system (e.g., ultrasonic welding system 400 of FIG. 4) is illustrated. Sonotrode 200 is substantially similar to sonotrode 100 (where like elements have like reference numerals or a reference numeral beginning with a “2” in lieu of a “1”), except sonotrode 200 includes an annular depression 202b2a. The description of such elements in connection with FIGS. 1A-1E is applicable to sonotrode 200 (unless explicitly or implicitly indicated otherwise) and thus omitted for conciseness. Body portion 202 defines a working surface 202b, an aperture 202c, and an edge 202d.

Referring now to FIG. 2B, a portion of a sonotrode 200′ (including a body portion 202′ terminating at a tip portion 202a′) configured for use in an ultrasonic welding system (e.g., ultrasonic welding system 400 of FIG. 4) is illustrated. Sonotrode 200′ is substantially similar to sonotrode 100′ (or a reference numeral beginning with a “2” in lieu of a “1”), except sonotrode 200′ includes an annular depression 202b2a. The description of such elements in connection with FIGS. 1A-1E is applicable to sonotrode 200′ (unless explicitly or implicitly indicated otherwise) and thus omitted for conciseness. Body portion 202′ defines a working surface 202b′, an aperture 202c′, an edge 202d′, a chamfered portion 202e, and a terminal end 202f (e.g., a surface parallel to working surface 202b′, a non-contact portion, a portion surrounding at least a portion of conductive pin 104, etc.).

FIGS. 2C-2D illustrate, respectively, working surfaces that may be disposed on embodiments of sonotrode 200 and/or sonotrode 200′, namely a working surface 202b1, and a working surface 202b3. It should be understood that certain repetitive or redundant reference numerals may be omitted for clarity.

Referring now to FIG. 2C, working surface 202b1 is illustrated. Working surface 202b1 defines annular depression 202b2a between aperture 202c, 202c′ and the outer edge (e.g., edge 202d, 202d′) of working surface 202b1. Working surface 202b1 includes a patterned portion 202b2 including a plurality of depressions 202b2n. In certain embodiments, the plurality of depressions 202b2n are a plurality of linear grooves arranged in a pattern (e.g., a grid-like pattern, a diamond shaped pattern, a “waffle”—shaped pattern, etc.).

In certain embodiments, a roughened portion may be used in lieu of (and/or in addition to) patterned portion 202b2. Such an embodiment is illustrated in FIG. 2D. FIG. 2D illustrates working surface 202b3 including a roughened portion 202b4. In certain embodiments, at least part of roughened portion 202b4 will have a surface roughness average of between: 0.01 micron and 100 microns; 0.05 micron and 5 microns; and/or 0.1 micron and 1 microns.

Referring to FIGS. 2C-2D, it should be understood that the working surfaces described are applicable to the area from annular depression 202b2a to aperture 202c, 202c′. The area radially outward from annular depression 202b2a may vary based on the particular embodiment, as indicated by the dotted circle.

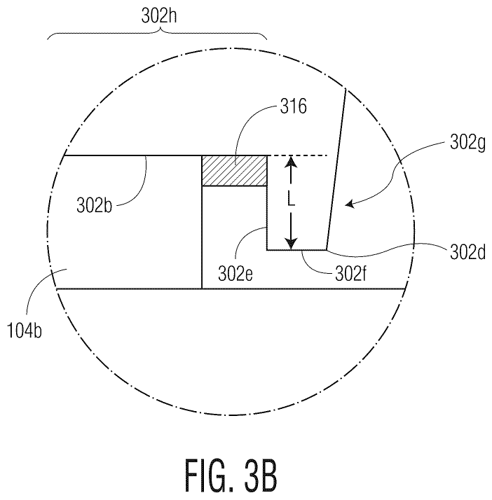

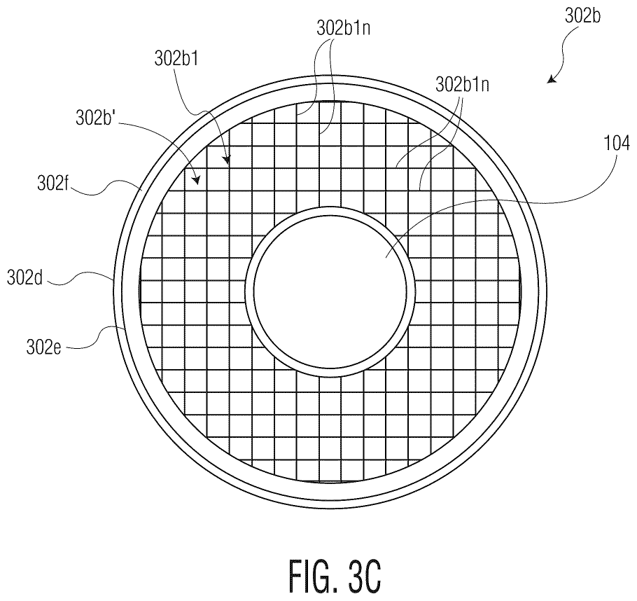

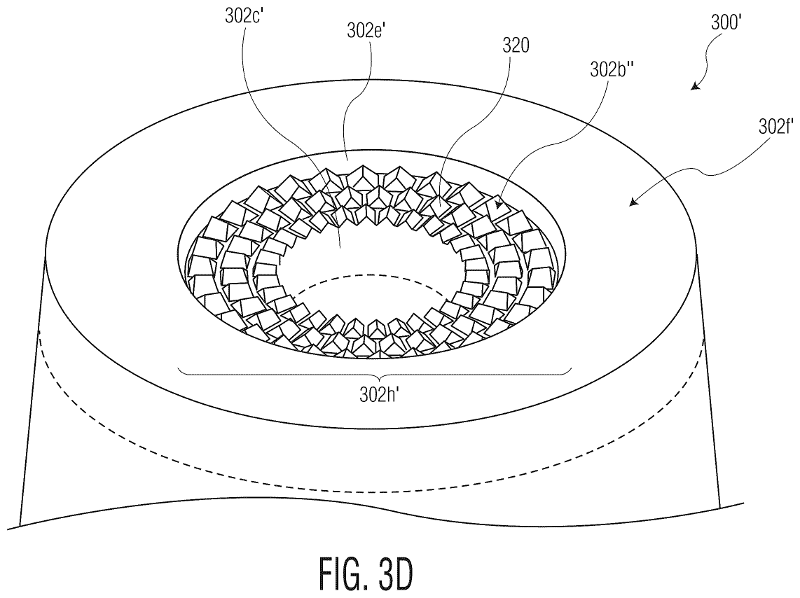

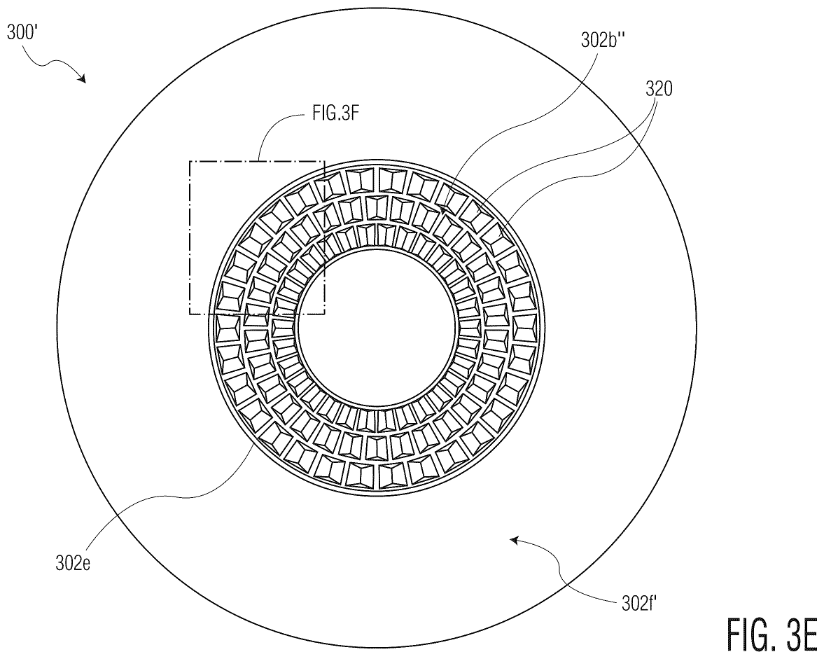

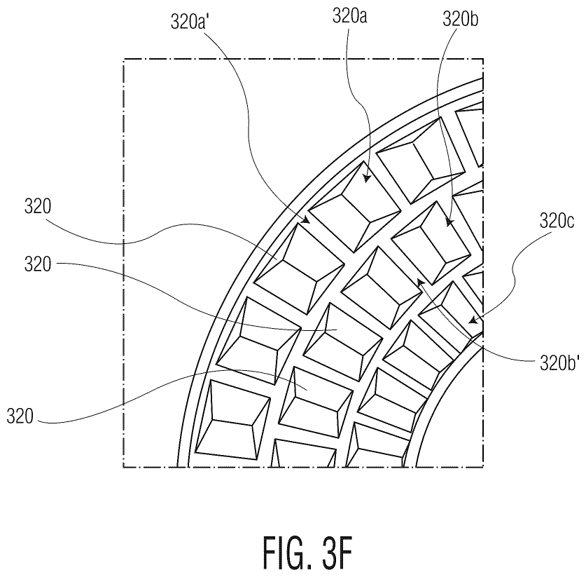

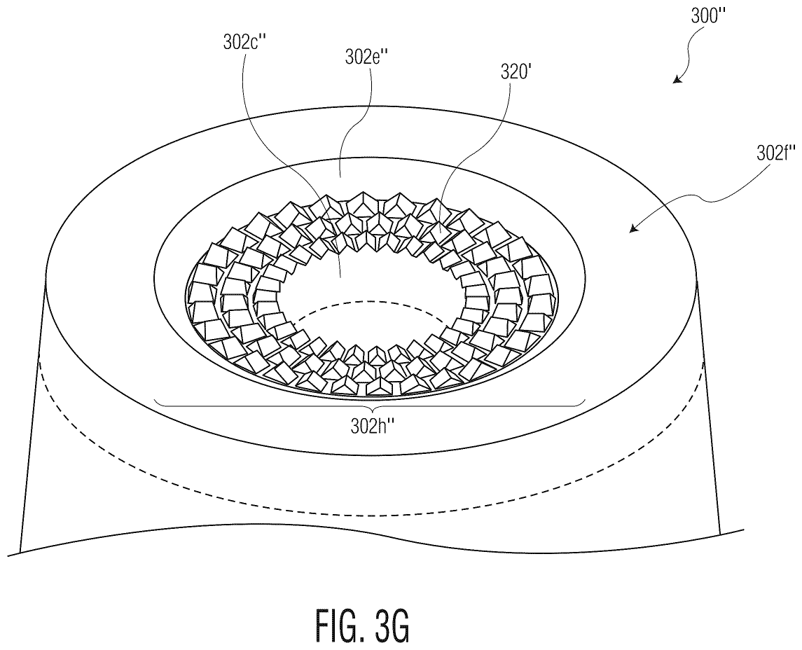

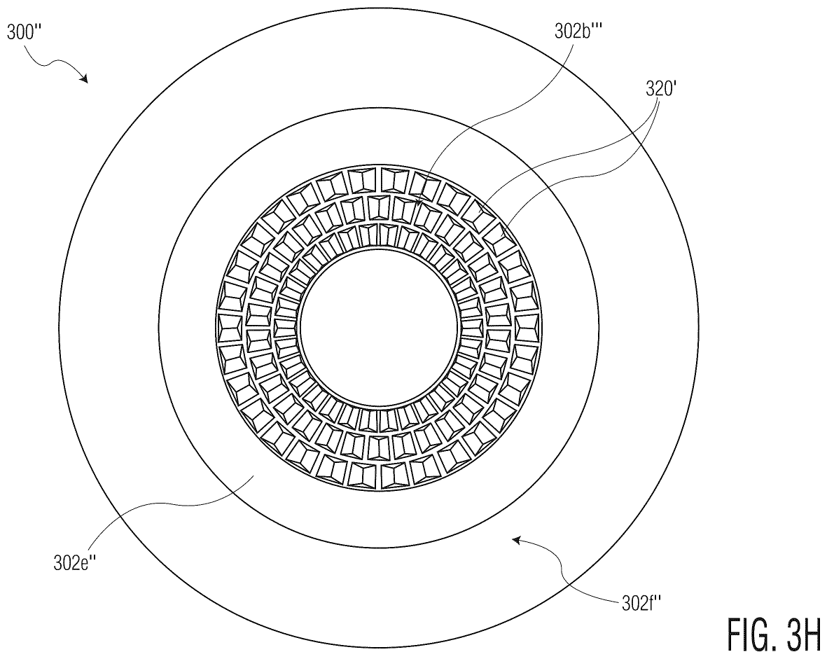

Referring now to FIG. 3A, a portion of a sonotrode 300 configured for use in an ultrasonic welding system (e.g., ultrasonic welding system 400 of FIG. 4) is illustrated. Sonotrode 300 is similar in certain aspects to sonotrode 100, sonotrode 100′, sonotrode 200, and sonotrode 200′, where like elements have like reference numerals (or a reference numeral beginning with a “3” in lieu of a “1” or “2”). The description of such elements in connection with FIGS. 1A-1E and FIGS. 2A-2D is applicable to sonotrode 300 (unless explicitly or implicitly indicated otherwise) and thus omitted for conciseness.

Sonotrode 300 is configured to ultrasonically weld conductive pin 104 to workpiece 106 during a welding process (e.g., an ultrasonic welding process). Conductive pin 104 is illustrated including body portion 104a and head portion 104b. Sonotrode 300 includes a body portion 302 terminating at tip portion 302a, where tip portion 302a includes a working surface 302b. Tip portion 302a defines a peripheral wall 302e (e.g., an inner circumferential edge) and also defines an aperture 302c. Aperture 302c (and/or body portion 302) is configured to hold conductive pin 104 during an ultrasonic welding process.

Sonotrode 300 defines a cavity 302h adjacent (e.g., perpendicular to) working surface 302b. Cavity 302h is defined (at least in part) by working surface 302b and peripheral wall 302e (e.g., including one or more annular edges). Head portion 104b (e.g., a pin head) of conductive pin 104 can be configured to be received by cavity 302h (e.g., configured such that head portion 104b fits within the dimensions of cavity 302h). Tip portion 302a includes a circumferential portion 302g (e.g., a substantially annular element) radially outward from working surface 302b, where circumferential portion 302g is partially defined by peripheral wall 302e, an edge 302d, and a terminal end 302f. Cavity 302h, peripheral wall 302e, and/or circumferential portion 302g are configured to mitigate outflow of a material 316 (e.g., dislodged material from conductive pin 104, whisker-forming material, metal fragments, etc.) generated in the formation of a weld.

More specifically, circumferential portion 302g (including peripheral wall 302e) may act as a structural barrier that mitigates long whiskers. By using sonotrode 300, including circumferential portion 302g surrounding head portion 104b of conductive pin 104, whiskers may be contained.

Referring now to FIG. 3B, a detailed view of a portion of sonotrode 300 is illustrated. As illustrated, cavity 302h, peripheral wall 302e, and/or circumferential portion 302g are configured (e.g., via the protruded length “L” from a portion of working surface 302b) to mitigate outflow of material 316 from a weld formed in a welding process (e.g., an ultrasonic welding process). Accordingly, in certain embodiments, working surface 302b can define any friction-inducing feature (e.g., in addition to, or in lieu of, a patterned portion 302b1 illustrated in FIG. 3C) sufficient for ultrasonic bonding operations.

Working surface 302b of sonotrode 300 may have any of a number of configurations (e.g., including linear depressions, patterned portions, roughened portions, smooth portions, etc.), as desired. Referring now to the example illustrated in FIG. 3C, a working surface 302b′ (e.g., an exemplary embodiment of working surface 302b) of sonotrode 300 is illustrated in greater detail. Working surface 302b′ includes patterned portion 302b1. In certain embodiments, working surface 302b′ may include a plurality of depressions 302b1n (e.g., a plurality of linear grooves). The plurality of depressions 302b1n (e.g., linear grooves) can be arranged in a pattern (e.g., a grid pattern). It should be understood that the plurality of depressions 302b1n (e.g., linear grooves) may be arranged in any pattern (e.g., rectangles, diamonds, pyramids, or any other pattern). In certain embodiments, working surface 302b may include a roughened portion in lieu of (at least a portion) of patterned portion 302b1 (e.g., see roughened portion 202b4 of FIG. 2D).

Referring now to the example shown in FIGS. 3D-3F, a working surface 302b″ (e.g., an exemplary embodiment of working surface 302b of FIG. 3A) of a sonotrode 300′ (e.g., an exemplary embodiment of sonotrode 300) is illustrated. Sonotrode 300′ is similar in many ways to sonotrode 300, where like elements have like reference numerals. In the illustrated embodiment, a terminal end 302f′ is noticeably larger/wider than terminal end 302f of sonotrode 300, as may be useful in certain applications (e.g., to provide additional torsional strength/rigidity to sonotrode 300′). Working surface 302b″ includes a plurality of protrusions 320 (e.g., pyramidal shaped protrusions, sawtooth shaped protrusions, or any other desired shape), along with cavities between the protrusions, disposed between a peripheral wall 302e′ of a cavity 302h′ and an aperture 302c′. The plurality of protrusions 320 may be, for example, formed using a laser (e.g., by laser scribing or the like). In the embodiment illustrated in FIGS. 3D-3F, the plurality of protrusions 320 are arranged in a plurality of concentric rings 320a, 320b, and 320c. Although three concentric rings 320a, 320b, and 320c are illustrated, any number of concentric rings may be provided. Gaps (e.g., valleys) are illustrated between adjacent ones of the plurality of protrusions 320. As shown in FIG. 3F, gaps 320a′ are provided between adjacent ones of the plurality of protrusions 320 in concentric ring 320a, while gaps 320b′ are provided between adjacent ones of the plurality of protrusions 320 in concentric ring 320b, etc. Gaps 320a′ are offset from gaps 320b′, based on (i) the placement of the ones of the plurality of protrusions 320 in concentric ring 320a versus (ii) the placement of the ones of the plurality of protrusions 320 in concentric ring 320b, etc. Thus, the plurality of protrusions 320 in one concentric ring (e.g., concentric ring 320a) are offset from those in an adjacent concentric ring (e.g., concentric ring 320b).

Further, according to certain embodiments of the invention (including that shown in FIGS. 3D-3F), the size of each of the plurality of protrusions 320 may be larger the farther away they are from a center of working surface 302b″ (e.g., away from aperture 302c′). Referring to FIGS. 3D-3F, the plurality of protrusions 320 in concentric ring 320b are larger than those in concentric ring 320c, and the plurality of protrusions 320 in concentric ring 320a are larger than those in concentric ring 320b.

Referring now to FIGS. 3G-3H, a portion of a sonotrode 300″ is illustrated. Sonotrode 300″ is substantially similar to sonotrode 300′, except a peripheral wall 302e″(e.g., a chamfered wall) is used in lieu of peripheral wall 302e′, where peripheral wall 302e″ is angled (e.g., chamfered, tapered, etc.). Due to the angle of peripheral wall 302e″, a terminal end 302f″ of sonotrode 300″ has a smaller area than that of terminal end 302f′ of sonotrode 300′. Peripheral wall 302e″ (e.g. chamfered wall) may be configured to align a conductive pin (e.g., conductive pin 104) with respect to an aperture 302c″ in connection with an ultrasonic welding process (e.g., the pin may become aligned through engagement with the peripheral wall in the presence of vacuum in the sonotrode). Sonotrode 300″ is illustrated including a plurality of protrusions 320′ disposed between peripheral wall 302e″ of a cavity 302h″ and aperture 302c″. A working surface 302b″ of sonotrode 300″ is substantially similar to that of working surface 302b′ of sonotrode 300′.

Referring now to FIG. 4, an ultrasonic welding system 400 is illustrated. Ultrasonic welding system 400 includes support structure 120 configured for supporting workpiece(s) 106. Ultrasonic welding system 400 is illustrated including an input workpiece supply 106a (e.g., a carrier such as a magazine handler for carrying a plurality of workpieces) configured to carry and/or supply one or more workpieces 106, an output workpiece supply 106b for receiving one or more workpieces 106, and a material handling system 430 configured to move workpieces 106 between input workpiece supply 106a and output workpiece supply 106b.

Ultrasonic welding system 400 can include a vacuum 426 (including vacuum piping 426a) to withdraw conductive pin 104 from a conductive pin supply (not illustrated). It should be understood that alternative conductive pin handling configurations (e.g., using a gripping mechanism, a magnetic handling mechanism, etc.) are contemplated within the scope of the invention. In certain applications, a camera 428 can be used to position the ultrasonic welding system 400 in connection with a pick-up or placement operation of conductive pin 104.

Ultrasonic welding system 400 includes a weld head assembly 418 configured to move along the x-axis, y-axis, z-axis, and/or a theta axis (Ø-axis) of ultrasonic welding system 400. It should be understood that not all of these motion axes are required in each application. Weld head assembly 418 includes an ultrasonic converter 422 configured to carry a sonotrode. More specifically, ultrasonic welding system 400 utilizes a sonotrode including a body portion terminating at a working surface, where the working surface defines an aperture configured to hold a conductive pin during an ultrasonic welding process.

The sonotrode included in ultrasonic welding system 400 may be any sonotrode within the scope of the invention, including but not limited to sonotrode 100 (e.g., sonotrode 100′), sonotrode 200 (e.g., 200′), sonotrode 300 (e.g., 300′, 300″), and/or any other sonotrode configured for use in ultrasonic welding system 400.

It should be understood that a control system 424 can be programmed to implement a welding operation in connection with a given sonotrode used in a particular welding operation. For example, a specific USG, amplitude, frequency, and/or motion profile can be used for a particular sonotrode.

Various embodiments of the invention described herein include linear depressions (e.g., linear depressions such as in FIGS. 1C-1E, 2C, and 3C). A depth of such linear depressions may be, for example, between: 1-1000 micrometers; 20-500 micrometers; or 50-100 micrometers; etc. A width of such linear depressions may be, for example, between: 1-2000 micrometers; 20-1000 micrometers; or 50-200 micrometers; etc.

Various embodiments of the invention described herein include an annular depression (e.g., annular depressions such as in FIGS. 1D, 2A, 2B, 2C, 2D). A depth of such annular depressions may be, for example, between: 1-1500 micrometers; 20-600 micrometers; or 50-200 micrometers; etc. A width of such annular depressions may be, for example, between: 1-2000 micrometers; 20-1000 micrometers; or 50-300 micrometers; etc.

Various embodiments of the invention include a chamfered portion included as part of the tip portion (e.g., chamfered portions, peripheral walls, etc.). The chamfered portion defines an angle with respect to a horizontal plane of a working surface. Exemplary ranges for the angle of the chamfered portions (and angled peripheral walls) may be, for example, between: 20°-70°; 30°-60°; and 40°-50°. A given range may be selected based on the application, such as an application requiring alignment of the sonotrode with respect to the conductive pin.

Various sonotrodes within the scope of the invention (including many of those described herein) include a body portion terminating at a tip portion. The body portion and the tip portion may be formed from a unitary piece of material (e.g., steel, stainless steel, a metal alloy, etc.). Alternatively, the body portion and the tip portion may be separate pieces coupled together (e.g., through brazing or other techniques) (e.g., see the dotted line separating the relevant body portion and tip portion in each of FIGS. 1A, 1B, 2A, 2B, and 3A). In connection with embodiments where the body portion and the tip portion are separate pieces, examples of the material of the body portion include: steel; stainless steel; a metal alloy; etc., and examples of materials of the tip portion include: ceramic; steel; carbide materials; and/or a metal alloy.

Aspects of the invention relate to the inclusion of various features at the tip portion of a sonotrode (e.g., linear depressions, annular depressions, protrusions, etc.). These features may be formed in the tip portion using any of a number of techniques such as laser scribing, laser irradiation, electro-discharge machining, etc.

Although the invention is illustrated and described herein with reference to specific embodiments, the invention is not intended to be limited to the details shown. Rather, various modifications may be made in the details within the scope and range of equivalents of the claims and without departing from the invention.

1. A sonotrode configured for use in an ultrasonic welding system comprising:
a body portion terminating at a tip portion, the tip portion including a working surface, the working surface defining an aperture configured to hold a conductive pin during an ultrasonic welding process, the working surface also defining a plurality of linear depressions, each of the plurality of linear depressions following a path that does not intersect the aperture.

2. The sonotrode of claim 1 wherein each of the plurality of linear depressions extends across the working surface.

3. The sonotrode of claim 1 wherein the plurality of linear depressions collectively define a star shaped pattern.

4. (canceled)

5. The sonotrode of claim 1 wherein the working surface includes a smooth portion, and wherein the plurality of linear depressions are disposed around a peripheral portion of the working surface.

6. The sonotrode of claim 1 wherein the working surface further defines an annular depression between the aperture and an edge of the working surface.

7. (canceled)

8. (canceled)

9. The sonotrode of claim 1 wherein the tip portion includes a chamfered portion between the working surface and a terminal end of the sonotrode.

10. The sonotrode of claim 9 wherein the chamfered portion is configured to align the conductive pin with respect to the aperture in connection with the ultrasonic welding process.

11. A sonotrode configured for use in an ultrasonic welding system comprising:
a body portion terminating at a tip portion, the tip portion including a working surface defining an aperture configured to hold a conductive pin during an ultrasonic welding process,
the working surface defining an annular depression between the aperture and an edge of the working surface.

12. The sonotrode of claim 11 wherein the working surface includes a roughened portion.

13. The sonotrode of claim 11 wherein the working surface includes a patterned portion.

14. The sonotrode of claim 11 wherein the working surface includes a plurality of depressions.

15. The sonotrode of claim 14 wherein the plurality of depressions are a plurality of linear grooves.

16. (canceled)

17. (canceled)

18. (canceled)

19. The sonotrode of claim 11 wherein the tip portion includes a chamfered portion between the working surface and a terminal end of the sonotrode.

20. The sonotrode of claim 19 wherein the chamfered portion is configured to align the conductive pin with respect to the aperture in connection with the ultrasonic welding process.

21. A sonotrode configured for use in an ultrasonic welding system comprising:
a body portion terminating at a tip portion, the tip portion including a working surface defining an aperture configured to hold a conductive pin during an ultrasonic welding process,
the sonotrode defining a cavity adjacent the working surface, the cavity being defined by the working surface and a peripheral wall, whereby a pin head of the conductive pin is configured to be received by the cavity.

22. The sonotrode of claim 21 wherein the peripheral wall is a circular wall that surrounds the working surface.

23. (canceled)

24. The sonotrode of claim 22 wherein the peripheral wall is configured to mitigate outflow of material resulting from the ultrasonic welding process.

25. (canceled)

26. (canceled)

27. (canceled)

28. (canceled)

29. The sonotrode of claim 21 wherein the working surface includes a plurality of protrusions.

30. (canceled)

31. (canceled)

32. (canceled)

33. (canceled)

34. The sonotrode of claim 21 wherein the peripheral wall is a chamfered wall between the working surface and a terminal end of the sonotrode.

35. The sonotrode of claim 34 wherein the chamfered wall is configured to align the conductive pin with respect to the aperture in connection with the ultrasonic welding process.

36. (canceled)

37. (canceled)

38. (canceled)
